(19) United States
(12) Patent Application Publication
(10) Pub. No.: US 2011/0184673 A1
(43) Pub. Date: Jul. 28, 2011

(54) METHOD AND DEVICE FOR FAULT LOCATION

(75) Inventors: Hideyuki Takani, Saitama (JP); Hideaki Sugiura, Tokyo (JP); Mika Ohashi, Tokyo (JP)

(73) Assignee: Kabushiki Kaisha Toshiba, Minato-ku (JP)

(21) Appl. No.: 13/003,407

(22) PCT Filed: Jul. 9, 2009
(86) PCT No.: PCT/JP09/03221

§ 371 Date: Mar. 18, 2011

(30) Foreign Application Priority Data
Jul. 9, 2008 (JP) 2008-179078

(51) Int. Cl. G06F 19/00; G01R 31/00

(52) U.S. Cl. 702/59

(57) ABSTRACT

A method for fault location is provided which can accurately perform a fault location process by a simple and direct calculation without requiring no synchronization of terminals. Data relating to the voltage and the current (vector quantity) at opposite ends of a power transmission line section to be located and a transmission line constant set in advance are used. When the distance x from a designated terminal A to a fault point F is an unknown quantity, the distance x can be calculated by solving a quadratic equation obtained by taking as the fault point a point where values of the second power of a fault point voltage in a fault phase when viewed from opposite ends of the section to be located are equal to each other.

### FIELD

This invention relates to a method and a device which calculates a distance up to a fault point using an electric current and a voltage of a power transmission line and a line constant of the power transmission line, and locates the fault point.

### BACKGROUND

In conventional methods for fault location, which determines an impedance (resistance) from an electric current flowing a power transmission line and a voltage thereof, calculates a distance up to a fault point, and locates the fault point, the fault location is performed using a condition that a fault point voltage (vector quantity) viewed from one end of a section to be located, is equal to that from the opposite end thereof (for example, see Non-Patent Document 1).

Referring to FIG. 19, a conventional method for fault location will be explained. FIG. 19(a) is a circuit diagram showing a power transmission line, FIG. 19(b) is a view showing a voltage distribution in the length direction of a power transmission line, and FIG. 19(c) is a view showing a relationship that can be established between voltage and current.

In a power transmission line 1 to be located shown in FIG. 19, when a fault point 2 (point F) is viewed from a terminal A of a section of line length L that has a line constant Z per unit length of a power transmission line, a voltage VF (vector quantity) is equal to that when viewed from the opposite terminal B of the section, as a result, the following expression (1) can be established.

\dot{V}_{A}−x·Ż·İ_{A}=\dot{V}_{F}=\dot{V}_{B}−(L−x)·Ż·İ_{B} (1)

In the expression (1), the left-hand side denotes a voltage when the fault point 2 (point F) is viewed from the terminal A, and the right-hand side denotes a voltage when the fault point 2 (point F) is viewed from the terminal B. The distance x from the terminal A to the fault point 2 (point F) is calculated by the following expression (2).

$$x = \frac{{\dot{V}}_{A} - {\dot{V}}_{B} + L \cdot \dot{Z} \cdot {\dot{I}}_{B}}{\dot{Z} \cdot ( {\dot{I}}_{A} + {\dot{I}}_{B} )} \qquad ( 2 )$$

The expression (2) can be established for voltage and current vector quantities at the opposite terminals, and requires synchronization of currents and voltages acquired at the opposite terminals, respectively. Therefore, a method is adopted, which synchronizes the terminals using sampling synchronization signals or GPS signals (Patent Document 1).

Further, there are methods that require no synchronization between terminals, for example, which focuses on magnitude (scalar) of the expression (1). This method successively calculates points, at which scalar quantities of the fault point voltage viewed from the opposite terminals are equal to each other, with starting from a virtual fault point (Patent Documents 2 and 3).
Patent Document 1: Japanese Patent Application Laid-open No. H03-282377(1991-282377)
Patent Document 2: Japanese Patent Application Laid-open No. H02-35379(1990-35379)
Patent Document 3: Japanese Patent Application Laid-open No. H02-228574(1990-228574)
Non-Patent Document 1: Shiro Hoki, Yoshikazu Kitani, “Sodensen no Kosyoten hyoteiki” Ohm-sha, 1957

In the methods that require no synchronization between terminals, as disclosed by Patent Documents 2 and 3, there is a merit that requires no transmission and reception circuit for sampling synchronization signals or GPS signals. On the other hand, since successive calculation is performed with starting from a virtual fault point, improvement of accuracy in this method requires very short intervals between successive calculation steps, as a result, a fault location device has to perform a complicated calculation and is subjected to a greater computational load.

Accordingly, this invention has as an object the provision of a method and device for fault location which can accurately perform a fault location process by a simple and direct calculation without requiring no synchronization between terminals.

### SUMMARY

In order to attain the above object, as one aspect of this invention, a method for fault location has the following technical features. The method for fault location, locates a fault point using a voltage and a current of each terminal in a power transmission line section to be located and a transmission line constant, and comprises the step of: calculating a distance from a designated terminal to a fault point by solving a quadratic equation obtained by taking as the fault point a point where values of the second power of a fault point voltage in a fault phase when viewed from opposite ends of the section to be located are equal to each other.

As another aspect of this invention, a device for fault location has the following technical features. The device for fault location, locates a fault point using a voltage and a current of each terminal in a power transmission line section to be located and a transmission line constant, and comprises an input processor and a location processor. The input processor is provided at each terminal in the power transmission line section to be located and has: a data input part which acquires terminal voltage and current signals and converts the signals into digital form, a data storage which has one or more type of setting value set in advance including a data retention time and stores an electrical quantity data in a memory based on the setting value when a fault occurs, and a data transmitter which transmits a stored data. The location processor has: a data acquisition part which acquires data transmitted from the input processor provided at each terminal via a transmission medium, a location computing part which sets in advance one or more type of setting value including the transmission line constant of the power transmission line to be located, uses the setting value and the current and voltage data acquired by the data acquisition part, and performs a location computation that calculates a distance from a designated terminal to a fault point by solving a quadratic equation obtained by taking as the fault point a point where values of the second power of a fault point voltage in a fault phase when viewed from opposite ends of the section to be located are equal to each other, and a location result output part which outputs a location result obtained by the location computing part.

With this invention, a method and device for fault location can be provided which can accurately perform a fault location process by a simple and direct calculation without requiring no synchronization between terminals.

### BRIEF DESCRIPTION OF THE DRAWINGS

FIG. 1 is a block diagram showing a fault location device for implementing fault location methods according to a first through fourth embodiments of this invention;

FIG. 2 is a flowchart showing a processing function of an input processor adopted in the first through fourth embodiments of this invention;

FIG. 3 is a flowchart showing a processing function of a location processor adopted in the first embodiment of this invention;

FIGS. 4(a) through 4(c) show a fault location method according to the first embodiment of this invention, FIG. 4(a) is a circuit diagram showing a power transmission line, FIG. 4(b) is a view showing a voltage distribution in the length direction of a power transmission line, and FIG. 4(c) is a view showing a relationship that can be established between voltage and current;

FIG. 5 is a flowchart showing a processing function of a location processor adopted in the second embodiment of this invention;

FIGS. 6(a) through 6(c) show a fault location method according to the second embodiment of this invention, FIG. 6(a) is a circuit diagram showing a power transmission line, FIG. 6(b) is a view showing a voltage fluctuation in the length direction of a power transmission line, and FIG. 6(c) is a view showing a relationship that can be established between voltage and current;

FIG. 7 is a flowchart showing a processing function of an input processor adopted in a modification of the second embodiment of this invention;

FIG. 8 is a flowchart showing a processing function of a location processor adopted in a modification of the second embodiment of this invention;

FIG. 9 is a flowchart showing a processing function of a location processor adopted in the third embodiment of this invention;

FIGS. 10(a) and 10(b) show a fault location method according to the third embodiment of this invention, FIG. 10(a) is a view showing an example of time series sampling data of voltage at a terminal A, and FIG. 10(b) is a view showing an example of time series sampling data of current at the terminal A;

FIGS. 11(a) and 11(b) show a fault location method according to the third embodiment of this invention, FIG. 11(a) is a view showing an example of time series sampling data of voltage at a terminal B, and FIG. 11(b) is a view showing an example of time series sampling data of current at the terminal B;

FIG. 12 shows a fault location method according to the third embodiment of this invention, in particular, an example of time series values calculated by fault location calculation;

FIG. 13 is a flowchart showing a processing function of a location processor adopted in the fourth embodiment of this invention;

FIGS. 14(a) and 14(b) show a fault location method according to the fourth embodiment of this invention, FIG. 14(a) is a view showing an example of time series sampling data of current at a terminal A, and FIG. 14(b) is a view showing an example of time series amplitude of current at the terminal A;

FIGS. 15(a) and 15(b) show a fault location method according to the fourth embodiment of this invention, FIG. 15(a) is a view showing an example of time series sampling data of current at a terminal B, and FIG. 15(b) is a view showing an example of time series amplitude of current at the terminal B;

FIG. 16 is a block diagram showing a fault location device for implementing a fault location method according to a fifth embodiment of this invention;

FIG. 17 is a flowchart showing a processing function of a location processor adopted in the fifth embodiment of this invention;

FIGS. 18(a) and 18(b) show a fault location method according to the fifth embodiment of this invention, FIG. 18(a) is a circuit diagram showing a power transmission line, and FIG. 18(b) is a view showing a relationship that can be established between voltage and current; and

FIGS. 19(a) through 19(c) show a conventional fault location method, FIG. 19(a) is a circuit diagram showing a power transmission line, FIG. 19(b) is a view showing a voltage distribution in the length direction of a power transmission line, and FIG. 19(c) is a view showing a relationship that can be established between voltage and current.

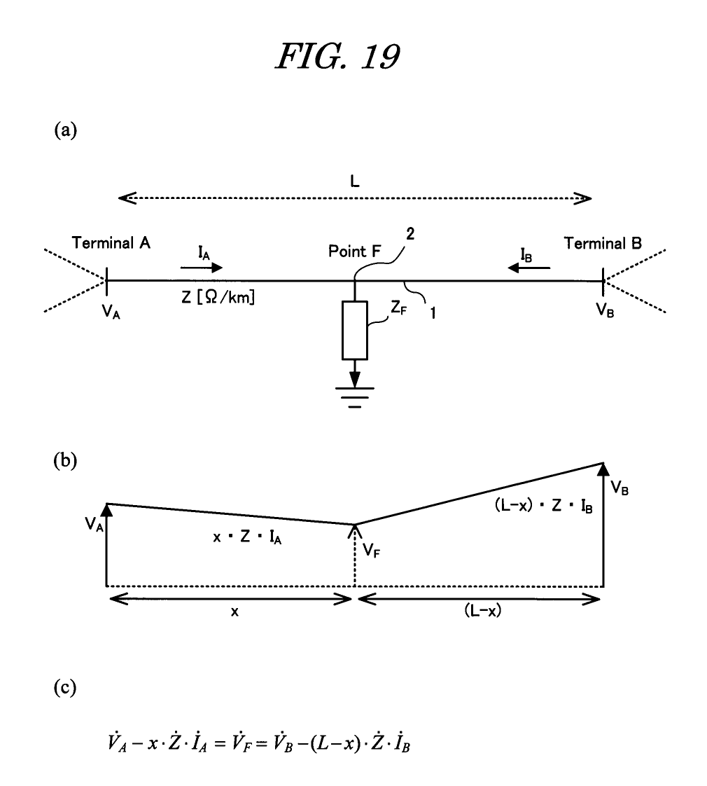

### EXPLANATION OF REFERENCE NUMERALS

1 . . . power transmission line section to be located
2 . . . fault point F
3 . . . branch point
10 . . . input processor
11 . . . data input part
12 . . . data storage
13 . . . data transmitter
20 . . . location processor
21 . . . data acquisition part
22 . . . location computing part
23 . . . location result output part

### DETAILED DESCRIPTION

Below, embodiments of method and device for fault location according to this invention will be explained in detail referring to the drawings. Note that elements in common with embodiments will be explained by appending the same symbols

### First Embodiment

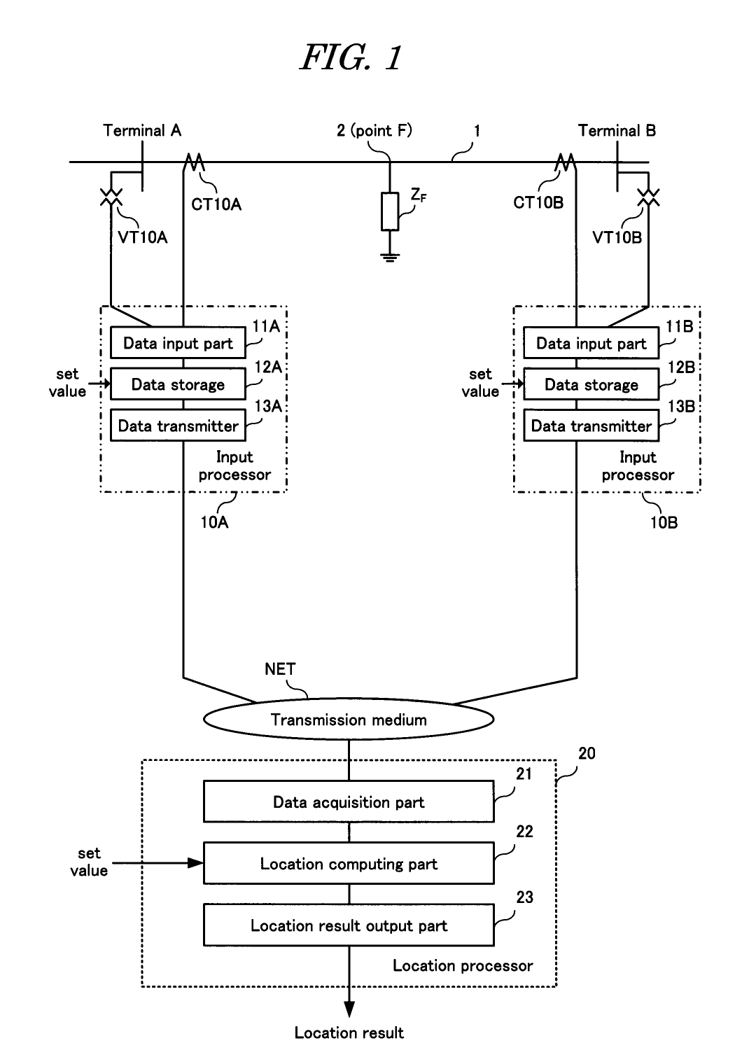

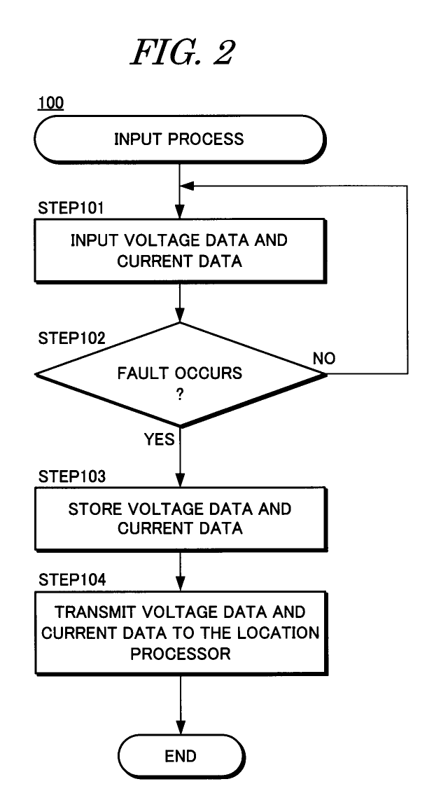

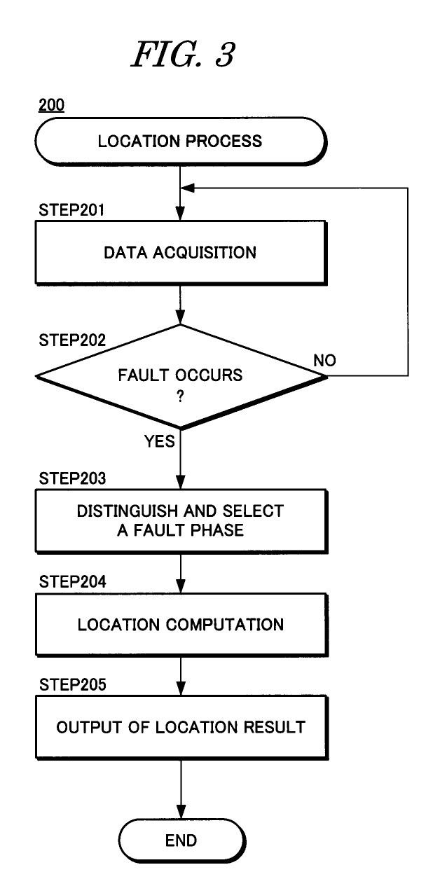

FIG. 1 is a block diagram showing a fault location device for implementing a fault location method according to the first embodiment of this invention, and FIGS. 2 and 3 are respectively flowcharts showing a processing function of an input processor and a location processor that configure the fault location device.

### {Configuration}

Before explanation of the fault location method according to this embodiment, first, a summary configuration of the fault location device will be explained referring to FIG. 1 through FIG. 3.

As shown in FIG. 1, symbol “1” denotes a power transmission line section with two terminals to be located, symbols “CT10A” and “CT10B” denote current transformers respectively provided at a terminal A and a terminal B of the power transmission line section 1, and symbols “VT10A” and “VT10B” denote voltage transformers respectively provided at a terminal A and a terminal B of the power transmission line section 1.

The fault location device according to this invention is composed of input processors 10A and 10B that are respectively provided at the terminal A and terminal B, and a location processor 20 that is connected to these input processors 10A and 10B via a transmission medium NET.

The input processor 10A provided at the terminal A is, for example, implemented in a digital computer such as a microprocessor, and has a data input part 11A which acquires voltage and current signals from the current transformer CT10A and the voltage transformer VT10A and converts the signals into digital form, a data storage 12A which has setting values set in advance including a data retention time and fault detection sensitivity and stores an electrical quantity data in a memory based on the setting values when a fault occurs, and a data transmitter 13A which transmits a stored data. Since the input processor 10B provided at the terminal B is configured the same as the input processor 10A, in the input processor 10B, for the same elements as those of the input processor 10A, “A” as the end of symbols is replaced with “B”, and an explanation thereof is omitted.

The location processor 20 also is, for example, implemented in a digital computer such as a microprocessor, and has a data acquisition part 21 which acquires data transmitted from the data transmitters 13A and 13B of the input processors 10A and 10B, a location computing part 22 which sets in advance setting values including the line length L and the transmission line constant Z (vector quantity) per unit length of the power transmission line section 1, and performs a location computation for locating a fault point based on the setting values and the current and voltage data acquired by the data acquisition part 21, and a location result output part 23 which outputs a location result obtained by the location computing part 22.

Next, an input process 100 that is performed as a processing function of the input processors 10A and 10B is explained referring to the flowchart shown in FIG. 2. Note that in the explanation of the input processors, when the distinction between the input processor on the terminal A side and the input processor on the terminal B side is not needed, “A” and “B” as the end of symbols are omitted.

The input processor 10, in the input process 100, at step 101, inputs a voltage and current data acquired from each terminal. This step 101 is a processing step performed by the data input part 11 shown in FIG. 1. Next, at step 102, the input processor 10 checks whether a fault occurs or not based on the setting values set in advance such as the data retention time and the fault detection sensitivity, and when determined that a fault occurs (“Yes” of step 102), at next step 103, stores the voltage and current data. These steps 102 and 103 are processing steps performed by the data storage 12 shown in FIG. 1.

After this, at next step 104, the input processor 10 transmits the voltage and current data of the fault occurrence time to the location processor 20. This step 104 is a processing step performed by the data transmitter 13 shown in FIG. 1.

Next, a location process 200 that is performed as a processing function of the location processor 20 is explained referring to the flowchart shown in FIG. 3.

The location processor 20, in the location process 200, at step 201, acquires data transmitted from the input processors 10A and 10B. This step 201 is a processing step performed by the data acquisition part 21 shown in FIG. 1.

After acquiring the data at step 201, when the location processor 20 has determined that a fault occurs at step 202 (“Yes” of step 202), the location processor 20 distinguishes and selects a fault phase from others at next step 203, and furthermore advances to step 204 and performs a location computation using the setting values set in advance such as a fault phase voltage data, each phase current data, the line length L and the transmission line constant Z (vector quantity) per unit length of the power transmission line section 1 at step 204. These steps 202, 203, and 204 are processing steps performed by the location computing part 22 shown in FIG. 1.

Subsequently, the location processor 20 outputs a location computation result at next step 205. This step 205 is performed by the location result output part 23 shown in FIG. 1.

### {Action}

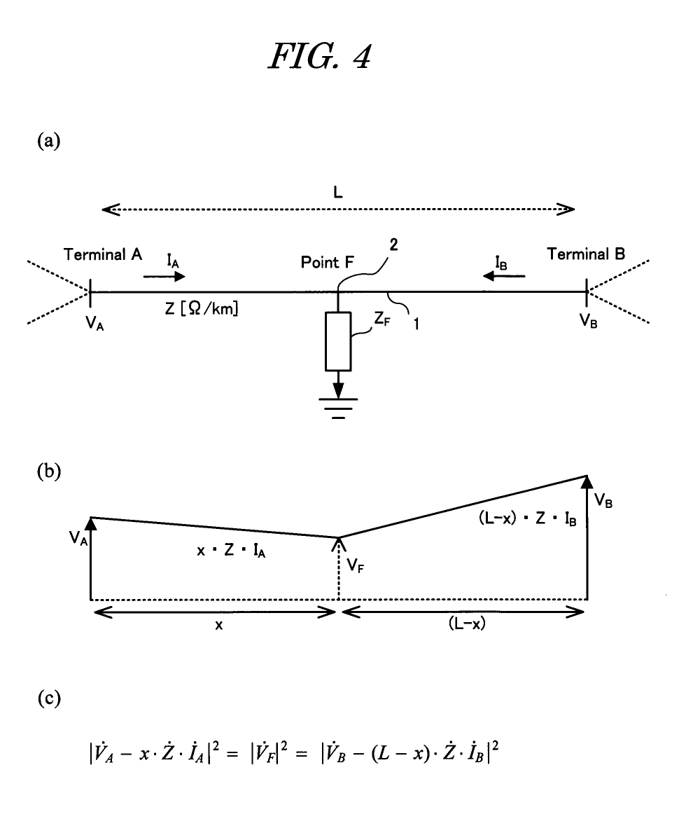

With the explanation described above, a processing function has been explained relating to the input processors 10A and 10B and the location processor 20 that compose the fault location device. Below, the fault location method according to this embodiment will be explained referring to FIG. 4.

FIGS. 4(a) through 4(c) show the fault location method according to this embodiment, FIG. 4(a) is a schematic diagram showing a state when a fault occurs in a power transmission line, FIG. 4(b) is a view showing a voltage distribution in the range that includes the terminals A and B at the opposite ends and a fault point F between them, and FIG. 4(c) is a view showing a relationship that can be established between voltage and current at the fault point.

In FIGS. 1 and 4, at each terminal of the terminals A and B of the power transmission line section 1 to be located, without performing the sampling synchronization between terminals, the voltage transformer VT10A, the current transformer CT10A, the voltage transformer VT10B and the current transformer CT10B, respectively sample a voltage V_{A} (vector quantity), a current I_{A} (vector quantity), a voltage V_{B} (vector quantity) and a current I_{B} (vector quantity), as electrical quantity signals when a fault occurs.

The input processors 10A and 10B respectively acquire the signals of the voltage V_{A} (vector quantity), the current I_{A} (vector quantity), the voltage V_{B} (vector quantity) and the current I_{B} (vector quantity), by the data input parts 11A and 11B, and convert the signals into a digital form.

The input processors 10A and 10B store the current and voltage data converted into the digital form to a memory of the data storages 12A and 12B based on the setting values such as the data retention time and the fault detection sensitivity, and furthermore, transmit the voltage and current digital data V_{A}, I_{A}, V_{B} and I_{B} to the location processor 20 by the data transmitters 13A and 13B.

In the location processor 20, the data acquisition part 21 acquires the digital data V_{A}, I_{A}, V_{B} and I_{B} of the fault occurrence time from the input processor 10A and 10B, and the location computing part 22 performs a location computation based on the setting values such as the line length L and the transmission line constant Z (vector quantity) per unit length, as follows.

First, when the values V_{A} and I_{A} acquired at the terminal A each are expressed in a complex number using an arbitrary reference phase, they can be expressed by the following expression (3).

V_{A}=V_{Ar}+jV_{Ax}

I_{A}=I_{Ar}+jI_{Ax} (3)

Here, for the magnitude of voltage (fault point voltage: V_{FA}) of the fault point 2 (point F) when viewed from the terminal A, the above-described expression (1) can be established, so the second power of the expression (1) also can be established.

Specifically, when the expression (1) is raised to the second power, the following expression (4) is obtained.

$$\begin{matrix}\begin{matrix}{\vert {V}_{FA} \vert}^{2} = {\vert {V}_{A} - x \cdot {Z}_{L} \cdot {I}_{A} \vert}^{2} \\ = {\vert {V}_{Ar} + j {V}_{Ax} - x ( R + j X ) ( {I}_{Ar} + j {I}_{Ax} ) \vert}^{2 } \\ = {\vert \begin{matrix}\{ {V}_{Ar} - x ( R \cdot {I}_{Ar} - X \cdot {I}_{Ax} ) \} + \\ j \{ {V}_{Ax} - x ( X \cdot {I}_{Ar} + R \cdot {I}_{Ax} ) \}\end{matrix} \vert}^{2} \\ = {\{ {V}_{Ar} - x ( R \cdot {I}_{Ar} - X \cdot {I}_{Ax} ) \}}^{2} + \\ {\{ {V}_{Ax} - x ( X \cdot {I}_{Ar} + R \cdot {I}_{Ax} ) \}}^{2}\end{matrix} \\ Here , & ( 4 ) \\ {[ ZI ]}_{Ar} = R \cdot {I}_{Ar} - X \cdot {{I}_{Ax} \\ [ ZI ]}_{Ax} = X \cdot {I}_{Ar} + R \cdot {I}_{Ax} & ( 5 )\end{matrix}$$

when the expression (5) is provided, the following expression (6) can be established.

$$\begin{matrix}{\vert {V}_{FA} \vert}^{2} = {( {V}_{Ar} - x \cdot {[ ZI ]}_{Ar} )}^{2} + {( {V}_{Ax} - x \cdot {[ ZI ]}_{Ax} )}^{2} \\ = ( {[ ZI ]}_{Ar}^{2} + {[ ZI ]}_{Ax}^{2} ) \cdot {x}^{2} - 2 ( {V}_{Ar} \cdot {[ ZI ]}_{Ar} + {V}_{Ax} \cdot {[ ZI ]}_{Ax} ) \cdot \\ x + {V}_{Ar}^{2} + {V}_{Ax}^{2}\end{matrix} \qquad ( 6 )$$

Next, when the values V_{B} and I_{B} acquired at the terminal B each are expressed in a complex number using an arbitrary reference phase (an asynchronous phase with terminal A can be used), they can be expressed by the following expression (7).

V_{B}=V_{Br}+jV_{Bx}

I_{B}=I_{Br}+jI_{Bx} (7)

Here, the second power of voltage (fault point voltage: V_{FB}) of the fault point 2 (point F) when viewed from the terminal B, can be expressed by the following expression (8).

$$\begin{matrix}\begin{matrix}{\vert {V}_{FB} \vert}^{2} = {\vert {V}_{B} - ( l - x ) \cdot {Z}_{L} \cdot {I}_{B} \vert}^{2} \\ = {\vert {V}_{Br} + j {V}_{Bx} - ( l - x ) ( R + j X ) ( {I}_{Br} + j {I}_{Bx} ) \vert}^{2} \\ = {\vert \begin{matrix}\{ {V}_{Br} - ( l - x ) ( R \cdot {I}_{Br} - X \cdot {I}_{Bx} ) \} + \\ j \{ {V}_{Bx} - ( l - x ) ( X \cdot {I}_{Br} + R \cdot {I}_{Bx} ) \}\end{matrix} \vert}^{2} \\ = {\{ {V}_{Br} - ( l - x ) ( R \cdot {I}_{Br} - X \cdot {I}_{Bx} ) \}}^{2} + \\ {\{ {V}_{Bx} - ( l - x ) ( X \cdot {I}_{Br} + R \cdot {I}_{Bx} ) \}}^{2}\end{matrix} \\ Here , & ( 8 ) \\ {[ ZI ]}_{Br} = R \cdot {I}_{Br} - X \cdot {{I}_{Bx} \\ [ ZI ]}_{Bx} = X \cdot {I}_{Br} + R \cdot {I}_{Bx} & ( 9 )\end{matrix}$$

when the expression (9) is provided, the following expression (10) can be established.

$$\begin{matrix}{\vert {V}_{FB} \vert}^{2} = {( {V}_{Br} - {( l - x ) [ ZI ]}_{Br} )}^{2} + {( {V}_{Bx} - {( l - x ) [ ZI ]}_{Bx} )}^{2} \\ = ( {[ ZI ]}_{Br}^{2} + {[ ZI ]}_{Bx}^{2} ) \cdot {( l - x )}^{2} - \\ 2 ( {V}_{Br} \cdot {[ ZI ]}_{Br} + {V}_{Bx} \cdot {[ ZI ]}_{Bx} ) \cdot ( l - x ) + {V}_{Br}^{2} + {V}_{Bx}^{2} \\ = ( {[ ZI ]}_{Br}^{2} + {[ ZI ]}_{Bx}^{2} ) \cdot {x}^{2} + \\ 2 \{ {{V}_{Br} [ ZI ]}_{Br} + {{V}_{Bx} [ ZI ]}_{Bx} + l ( {[ ZI ]}_{Br}^{2} + {[ ZI ]}_{Bx}^{2} ) \} \cdot x + \\ {l}^{2} ( {[ ZI ]}_{Br}^{2} + {[ ZI ]}_{Bx}^{2} ) - 2 l ( {{V}_{Br} [ ZI ]}_{Br} + {{V}_{Bx} [ ZI ]}_{Bx} ) + \\ {V}_{Br}^{2} + {V}_{Bx}^{2}\end{matrix} \qquad ( 10 )$$

In addition, since the expression (6) is equivalent to the expression (10), when from the following expression (11) the subsequent expression (12) is eliminated, a quadratic equation for x can be obtained as shown in the expression (13).

|v_{FA}|²=|v_{FB}|²

∴|v_{F}|²≡|v_{FA}|²=|v_{FB}|² (11)

|v_{F}|² (12)

A·x²−2B·x+C=0 (13)

Here, values A, B and C can be expressed by the following expression (14).

A=[ZI]_{Ar}²+[ZI]_{Ax}²−[ZI]_{Br}²−[ZI]_{Bx}²

B=V_{Ar}[ZI]_{Ar}+V_{Ax}[ZI]_{Ax}+V_{Br}[ZI]_{Br}+V_{Bx}[ZI]_{Bx}−l([ZI]_{Br}²+[ZI]_{Bx}²)

C=V_{Ar}²+V_{Ax}²−V_{Br}²−V_{Bx}²+2l(V_{Br}[ZI]_{Br}+V_{Bx}[ZI]_{Bx})−l²([ZI]_{Br}²+[ZI]_{Bx}²) (14)

By solving the expression (13) using the quadratic formula to find the expression (15), the distance x (0≦x≦L) up to the fault point can be found.

$$x = \frac{B \pm \sqrt{{B}^{2} - A C}}{A} \qquad ( 15 )$$

As described above, in the first embodiment, a location computation is performed which calculates a distance from a designated terminal to a fault point by using data transmitted from the input processor provided at each terminal and the setting values such as the transmission line constant, and solving a quadratic equation obtained by taking as the fault point a point where values of the second power of a fault point voltage in a fault phase when viewed from opposite ends of the transmission line section to be located are equal to each other. With the embodiment, the distance x up to the fault point can be accurately calculated by a simple and direct calculation without requiring no synchronization between terminals.

### Second Embodiment

The configuration of a fault location device for implementing a fault location method according to the second embodiment, is the same as that of the first embodiment. In addition, the input processor 10 also is the same as that of the first embodiment.

Since a different feature of this embodiment from the first embodiment, is only a part of the processing function of the location processor 20, below, the different processing function of the location processor 20 is mainly explained.

### {Configuration}

As with the first embodiment, in this embodiment, the input processors 10 shown in FIG. 1, acquire the signals of the voltage V_{A} (vector quantity), the current I_{A} (vector quantity), the voltage V_{B} (vector quantity) and the current I_{B} (vector quantity), which are sampled at the terminals A and B of the power transmission line section 1 to be located, regardless of the synchronous sampling or asynchronous sampling between the terminals.

In addition, the location processor 20 sets the line length L and the transmission line constant Z (vector quantity) per unit length, and calculates the distance x from the terminal A to the fault point F using a quantity transformed by a mode transformation.

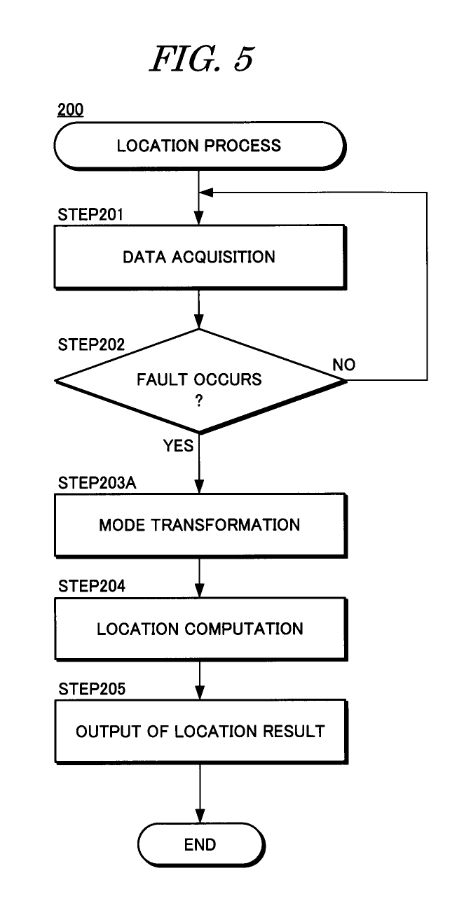

FIG. 5 is a flowchart showing a location process 200 that is performed as a processing function of the location processor 20 in the fault location device for implementing the fault location method according to the second embodiment.

In FIG. 5, the location processor 20 acquires data at step 201. This step 201 is a processing step performed by the data acquisition part 21 shown in FIG. 1.

After acquiring the data at step 201, when the location processor 20 has determined that a fault occurs at step 202 (“Yes” of step 202), the location processor performs a mode transformation at next step 203A, subsequently, performs a location computation using the setting values such as each phase voltage data, each phase current data, and the transmission line constant at step 204. These steps 202, 203A, and 204 are processing steps performed by the location computing part 22 shown in FIG. 1.

Subsequently, the location processor 20 outputs a location computation result at next step 205. This step 205 is performed by the location result output part 23 shown in FIG. 1.

### {Action}

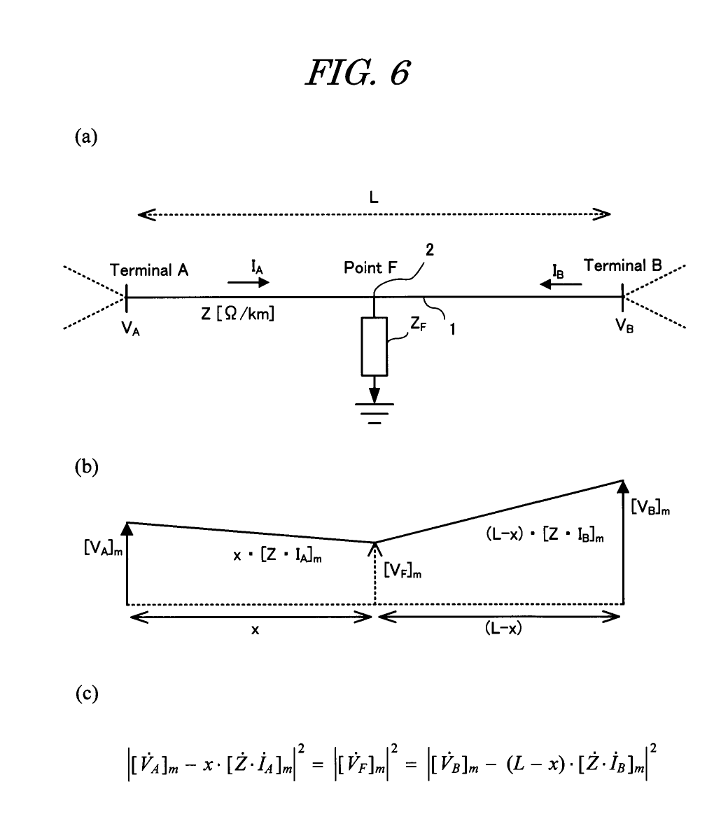

With the explanation described above, a processing function has been explained relating to the input processors 10A and 10B and the location processor 20 that compose the fault location device. Below, the fault location method according to this embodiment will be explained referring to FIG. 6.

FIGS. 6(a) through 6(c) show the fault location method according to the second embodiment, FIG. 6(a) is a schematic diagram showing a state when a fault occurs in a power transmission line, FIG. 6(b) is a view showing a voltage distribution in the range that includes the terminals at the opposite ends and a fault point between them, and FIG. 6(c) is a view showing a relationship that can be established between voltage and current at the fault point.

The fault location method explained as the first embodiment, which is a method for directly handling three phases for each phase, the application of the expressions (4) and (8) to a fault phase among the phases “a”, “b”, “c”, “ab”, “bc”, “ca” and “abc”, allows to easily calculate the distance up to the fault point 2 (point F). However, the application of the expressions (4) and (8) to phase “b” when the fault phase is phase “a”, increases the influence of errors in calculation, as a result, in general, shows a tendency to be difficult to perform the computation. Therefore, if the mode transformation of this embodiment were not used, in general, it would be necessary to perform a step for distinguishing and selecting a fault phase (step 203), as explained above referring to FIG. 3.

Specifically, if the mode transformation of this embodiment were not used, the expressions (4) and (8) would be expressed by the following expressions (16) and (17) in case of phase “a” fault, and by other expressions in case of phase “b” fault or phase “c” fault. In this case, first a step for distinguishing and selecting a fault phase would be performed, and subsequently, a step for calculating the distance up to the fault would be performed using an expression that corresponds to the distinguished and selected fault phase.

$$\begin{matrix} {\vert {\dot{V}}_{Aa} - x \cdot {\dot{Z}}_{a \#} \cdot {\dot{I}}_{Aabc} \vert}^{2} = {\vert {\dot{V}}_{Fa} \vert}^{2} = {\vert {\dot{V}}_{Ba} - ( L - x ) \cdot {\dot{Z}}_{a \#} \cdot {\dot{I}}_{Babc} \vert}^{2} \\ Reference phase expression of expressions ( 4 ) and ( 8 ) \\ when using phase {}_{}^{″}{a}{}_{}^{″} as a reference phase & ( 16 ) \\ {\vert {\dot{V}}_{Aa} - x \cdot [ \begin{matrix}{Z}_{aa} & {Z}_{ab} & {Z}_{a c}\end{matrix} ] \cdot [ \begin{matrix}{I}_{Aa} \\ {I}_{Ab} \\ {I}_{Ac}\end{matrix} ] \vert}^{2} = {\vert {\dot{V}}_{Fa} \vert}^{2} = {\vert {\dot{V}}_{Ba} - ( L - x ) \cdot [ \begin{matrix}{Z}_{aa} & {Z}_{ab} & {Z}_{a c}\end{matrix} ] \cdot [ \begin{matrix}{I}_{Ba} \\ {I}_{Bb} \\ {I}_{Bc}\end{matrix} ] \vert}^{2} \\ Matrix expression of expressions ( 4 ) and ( 8 ) when \\ using phase {}_{}^{″}{a}{}_{}^{″} as a reference phase & ( 17 )\end{matrix}$$

On the other hand, in this embodiment, the quantity obtained by a mode transformation such as a quantity of positive phase obtained by method of symmetrical coordinates, is used, as a result, it is unnecessary to perform the step for distinguishing and selecting a fault phase.

Below, a specific example of using a mode transformation of a quantity of positive phase obtained by method of symmetrical coordinates, is shown in the following expressions (18) and (19).

$$\begin{matrix}{\vert {\dot{V}}_{Aabc} - x \cdot {\dot{Z}}_{abc} \cdot {\dot{I}}_{Aabc} \vert}^{2} = {\vert {\dot{V}}_{Fabc} \vert}^{2} = {\vert {\dot{V}}_{Babc} - ( L - x ) \cdot {\dot{Z}}_{abc} \cdot {\dot{I}}_{Babc} \vert}^{2} \\ Three phase expression of expression ( 4 ) and ( 8 ) \\ when using no reference phase & ( 18 ) \\ {\vert [ \begin{matrix}{V}_{Aa} \\ {V}_{Ab} \\ {V}_{A c}\end{matrix} ] - x \cdot [ \begin{matrix}{Z}_{aa} & {Z}_{ab} & {Z}_{a c} \\ {Z}_{b a} & {Z}_{bb} & {Z}_{bc} \\ {Z}_{ca } & {Z}_{cb} & {Z}_{cc}\end{matrix} ] \cdot [ \begin{matrix}{I}_{Aa} \\ {I}_{Ab} \\ {I}_{Ac}\end{matrix} ] \vert}^{2} = {\vert [ \begin{matrix}{V}_{Fa} \\ {V}_{Fb} \\ {V}_{Fc}\end{matrix} ] \vert}^{2} = {\vert [ \begin{matrix}{V}_{Ba} \\ {V}_{Bb} \\ {V}_{Bc}\end{matrix} ] - ( L - x ) \cdot [ \begin{matrix}{Z}_{aa} & {Z}_{ab} & {Z}_{a c} \\ {Z}_{ba} & {Z}_{bb} & {Z}_{bc} \\ {Z}_{ca} & {Z}_{cb} & {Z}_{cc}\end{matrix} ] \cdot [ \begin{matrix}{I}_{Ba} \\ {I}_{Bb} \\ {I}_{Bc}\end{matrix} ] \vert}^{2} \\ Three phase matrix expression of expression ( 4 ) and ( 8 ) \\ when using no reference phase & ( 19 )\end{matrix}$$

When a mode transformation matrix, which is obtained by a mode transformation of a quantity of positive phase obtained by a method of symmetrical coordinates and which is shown in the following expression (20), is applied to the expression (19), the expression (21) can be obtained.

$$\begin{matrix} A = \frac{1}{3} [ \begin{matrix}1 & a & {a}^{2}\end{matrix} ] \\ Here , a = - \frac{1}{2} + j \frac{\sqrt{3}}{2} , {a}^{2} = - \frac{1}{2} - j \frac{\sqrt{3}}{2} & ( 20 ) \\ {\vert A [ \begin{matrix}{V}_{Aa} \\ {V}_{Ab} \\ {V}_{Ac}\end{matrix} ] - x \cdot A [ \begin{matrix}{Z}_{aa} & {Z}_{ab} & {Z}_{a c} \\ {Z}_{ba} & {Z}_{bb} & {Z}_{bc} \\ {Z}_{ca} & {Z}_{cb} & {Z}_{cc}\end{matrix} ] \cdot [ \begin{matrix}{I}_{Aa} \\ {I}_{Ab} \\ {I}_{Ac}\end{matrix} ] \vert}^{2} = {\vert A [ \begin{matrix}{V}_{Fa} \\ {V}_{Fb} \\ {V}_{Fc}\end{matrix} ] \vert}^{2} = {\vert A [ \begin{matrix}{V}_{Ba} \\ {V}_{Bb} \\ {V}_{Bc}\end{matrix} ] - ( L - x ) \cdot A [ \begin{matrix}{Z}_{aa} & {Z}_{ab} & {Z}_{a c} \\ {Z}_{ba} & {Z}_{bb} & {Z}_{bc} \\ {Z}_{ca} & {Z}_{cb} & {Z}_{cc}\end{matrix} ] \cdot [ \begin{matrix}{I}_{Ba} \\ {I}_{Bb} \\ {I}_{Bc}\end{matrix} ] \vert}^{2} & ( 21 )\end{matrix}$$

In addition, when a transformation matrix, which is obtained by a mode transformation of a quantity a obtained by a Clarke transformation and which is shown in the following expression (22), is applied to the expression (19), the expression (23) can be obtained.

$$\begin{matrix} C = \frac{1}{3} [ \begin{matrix}2 & - 1 & - 1\end{matrix} ] & ( 22 ) \\ {\vert C [ \begin{matrix}{V}_{Aa} \\ {V}_{Ab} \\ {V}_{Ac}\end{matrix} ] - x \cdot C [ \begin{matrix}{Z}_{aa} & {Z}_{ab} & {Z}_{a c} \\ {Z}_{ba} & {Z}_{bb} & {Z}_{bc} \\ {Z}_{ca} & {Z}_{cb} & {Z}_{cc}\end{matrix} ] \cdot [ \begin{matrix}{I}_{Aa} \\ {I}_{Ab} \\ {I}_{Ac}\end{matrix} ] \vert}^{2} = {\vert C [ \begin{matrix}{V}_{Fa} \\ {V}_{Fb} \\ {V}_{Fc}\end{matrix} ] \vert}^{2} = {\vert C [ \begin{matrix}{V}_{Ba} \\ {V}_{Bb} \\ {V}_{Bc}\end{matrix} ] - ( L - x ) \cdot C [ \begin{matrix}{Z}_{aa} & {Z}_{ab} & {Z}_{a c} \\ {Z}_{ba} & {Z}_{bb} & {Z}_{bc} \\ {Z}_{ca} & {Z}_{cb} & {Z}_{cc}\end{matrix} ] \cdot [ \begin{matrix}{I}_{Ba} \\ {I}_{Bb} \\ {I}_{Bc}\end{matrix} ] \vert}^{2} & ( 23 )\end{matrix}$$

Here, when a state of after applying a mode transformation matrix is denotes by “[ ]m”, the expression (23) is changed into the following expression (24).

$${\vert {[ \begin{matrix}{V}_{Aa} \\ {V}_{Ab} \\ {V}_{Ac}\end{matrix} ]}_{m} - x \cdot {[ [ \begin{matrix}{Z}_{aa} & {Z}_{ab} & {Z}_{a c} \\ {Z}_{ba} & {Z}_{bb} & {Z}_{bc} \\ {Z}_{ca} & {Z}_{cb} & {Z}_{cc}\end{matrix} ] \cdot [ \begin{matrix}{I}_{Aa} \\ {I}_{Ab} \\ {I}_{Ac }\end{matrix} ] ]}_{m} \vert}^{2} = {\vert {[ \begin{matrix}{V}_{Fa} \\ {V}_{Fb} \\ {V}_{Fc}\end{matrix} ]}_{m} \vert}^{2} {\vert {[ \begin{matrix}{V}_{Ba} \\ {V}_{Bb} \\ {V}_{Bc}\end{matrix} ]}_{m} - ( L - x ) \cdot {[ [ \begin{matrix}{Z}_{aa} & {Z}_{ab} & {Z}_{a c} \\ {Z}_{ba} & {Z}_{bb} & {Z}_{bc} \\ {Z}_{ca} & {Z}_{cb} & {Z}_{cc}\end{matrix} ] \cdot [ \begin{matrix}{I}_{Ba} \\ {I}_{Bb} \\ {I}_{Bc}\end{matrix} ] ]}_{m} \vert}^{2} \qquad ( 24 )$$

This expression (24) can be expressed more simply, as shown in the following expression (25).

|[\dot{V}_{A}]ₘ−x·[Ż·İ_{A}]ₘ|²=|[\dot{V}_{F}]ₘ|¹−|[\dot{V}_{B}]ₘ−(L−x)·[Ż·İ_{B}]ₘ|² (25)

In addition, when positive phase sequence impedances Z₁₁, Z₁₂ and Z₁₀ are applied to the impedance part of the expression (21), the following expression (26) can be obtained.

$${\vert A [ \begin{matrix}{V}_{Aa} \\ {V}_{Ab} \\ {V}_{A c}\end{matrix} ] - x \cdot [ \begin{matrix}{Z}_{11} & {Z}_{12} & {Z}_{10}\end{matrix} ] \cdot A [ \begin{matrix}{I}_{Aa} \\ {I}_{Ab} \\ {I}_{Ac}\end{matrix} ] \vert}^{2} = {\vert A [ \begin{matrix}{V}_{Fa} \\ {V}_{Fb} \\ {V}_{Fc}\end{matrix} ] \vert}^{2} = {\vert A [ \begin{matrix}{V}_{Ba} \\ {V}_{Bb} \\ {V}_{Bc}\end{matrix} ] - ( L - x ) \cdot [ \begin{matrix}{Z}_{11} & {Z}_{12} & {Z}_{10}\end{matrix} ] \cdot A [ \begin{matrix}{I}_{Ba} \\ {I}_{Bb} \\ {I}_{Bc}\end{matrix} ] \vert}^{2} \qquad ( 26 )$$

From the nature of the mode transformation, it is applicable to any of a single phase fault, a two phase fault and a three phase fault when being of a quantity of positive phase, it is applicable to a single phase fault and a two phase fault when being of a quantity of reversed phase, and it is applicable to a single phase fault when being of a quantity of zero phase, respectively without performing a step for distinguishing and selecting a fault phase.

The method of this embodiment, as with the first embodiment, as shown in FIG. 6, includes acquiring the signals of the voltage V_{A} (vector quantity), the current I_{A} (vector quantity), the voltage V_{B} (vector quantity) and the current I_{B} (vector quantity), which are sampled at the terminals A and B of the power transmission line section 1 to be located, regardless of the synchronous sampling or asynchronous sampling between the terminals, and using the line length L and the transmission line constant Z (vector quantity) per unit length. In particular, in this embodiment, as described above, a transformed quantity obtained by a mode transformation is used, and values of the second power of a fault point voltage [V_{F}]m (vector quantity) when viewed from the opposite ends of the transmission line section are equal to each other, as a result, for the distance x from the terminal A to the fault point 2 (F), the above-described expression (25) can be found. When the following expression (27) is eliminated from the expression (25), a quadratic equation for x can be obtained.

|[\dot{V}_{F}]ₘ|² (27)

Thus, the distance x up to the fault point can be calculated by solving the obtained quadratic equation for x.

### Modification of Second Embodiment

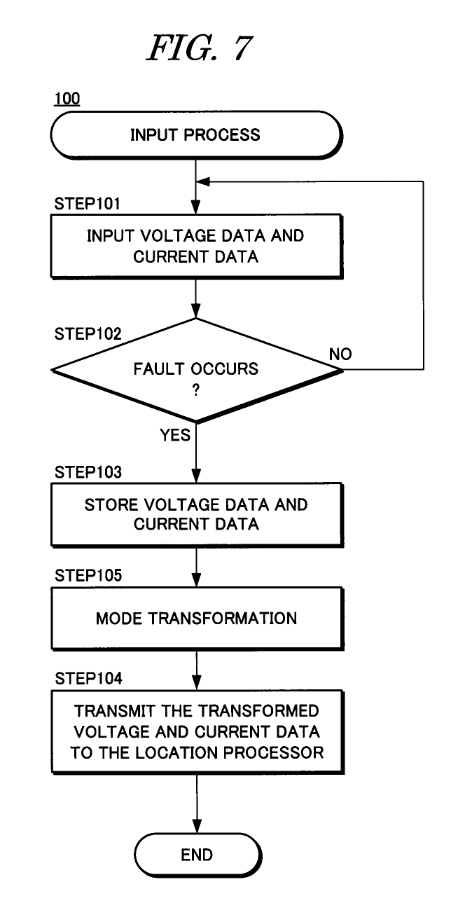

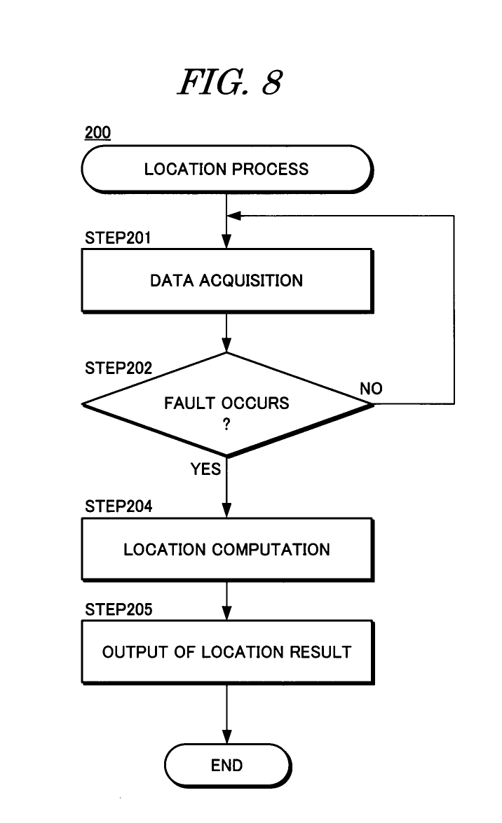

Note that, in the second embodiment described above, a mode transformation of voltage and current is performed by, but not limited to the location processor 20. The data storage 12 may be provided with a mode transformation function, and, as shown in FIG. 7, the input processor 10, in the input process 100, after a processing step 103 which store voltage and current data, may perform a processing step 105 for mode transformation which transforms the mode of voltage and current by the data storage 12. In this case, it is unnecessary to perform a mode transformation of voltage and current in the location processor 20, so the processing step 203A for mode transformation is removed from the location process 200 performed by the location processor 20, as shown in FIG. 8.

### {Advantageous Effects}

As described above, with the second embodiment and the modification thereof, as with the first embodiment, the distance x up to the fault point can be calculated by a simple and direct calculation without requiring no synchronization between terminals. Moreover, in this embodiment, as a result of using a transformed quantity obtained by a mode transformation, a fault location can be performed without distinguishing and selecting a fault phase among the phases “a”, “b”, “c”, “ab”, “bc”, “ca” and “abc”. For example, the mode transformation is applicable to any of a single phase fault, a two phase fault and a three phase fault when being of a quantity of positive phase, it is applicable to a single phase fault and a two phase fault when being of a quantity of reversed phase, and it is applicable to a single phase fault when being of a quantity of zero phase, respectively without performing a step for distinguishing and selecting a fault phase. Consequently, the total volume of calculation can be reduced and a fault location can be performed more efficiently.

### Third Embodiment

The configuration of a fault location device for implementing a fault location method according to the third embodiment, is the same as that of the first and second embodiments. In addition, the input processor 10 also is the same as that of the first and second embodiments.

Since a different feature of this embodiment from the first and second embodiments, is only a part of the processing function of the location processor 20, below, the different processing function of the location processor 20 is mainly explained.

### {Configuration}

As with the first and second embodiments, in this embodiment, the input processors 10 shown in FIG. 1, acquire the signals of the voltage V_{A} (vector quantity), the current I_{A} (vector quantity), the voltage V_{B} (vector quantity) and the current I_{B} (vector quantity), which are sampled at the terminals A and B of the power transmission line section 1 to be located, regardless of the synchronous sampling or asynchronous sampling between the terminals.

In addition, the location processor 20, based on the setting values set in advance such as the line length L and the transmission line constant Z (vector quantity) per unit length, calculates the distance x from the terminal A to the fault point F using a vector quantity (phasor quantity).

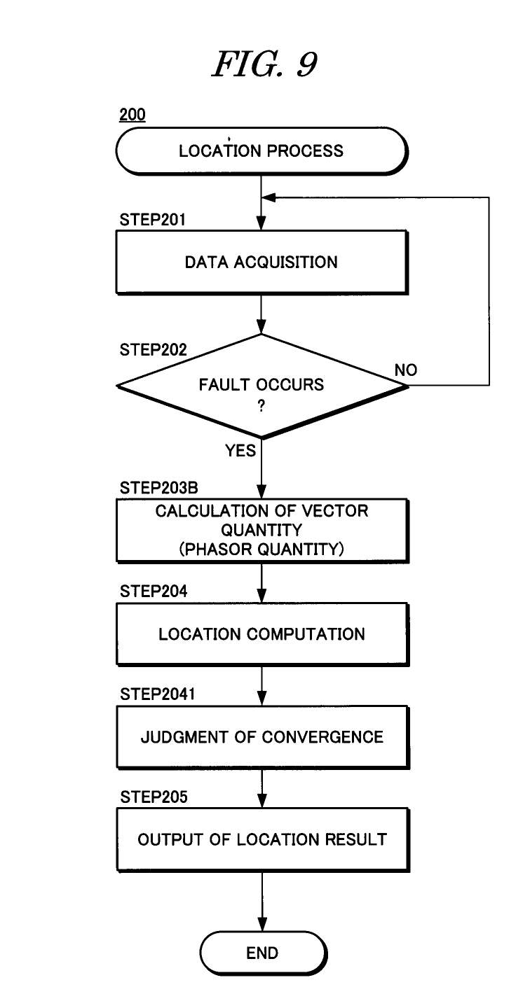

FIG. 9 is a flowchart showing a location process 200 that is performed as a processing function of the location processor 20 in the fault location device for implementing the fault location method according to the third embodiment.

In FIG. 9, the location processor 20 acquires data at step 201. This step 201 is a processing step performed by the data acquisition part 21 shown in FIG. 1.

After acquiring the data at step 201, when the location processor 20 has determined that a fault occurs at step 202 (“Yes” of step 202), the location processor 20 calculates a vector quantity (phasor quantity) at next step 203B, subsequently, performs a location computation using the setting values such as each phase voltage data, each phase current data, and the transmission line constant at step 204. These steps 202, 203B, and 204 are processing steps performed by the location computing part 22 shown in FIG. 1.

After step 204, the location processor 20 makes a judgment of convergence at subsequent step 2041 by the location computing part 22, and furthermore, outputs a location computation result at next step 205. This step 205 is performed by the location result output part 23 shown in FIG. 1.

### {Action}

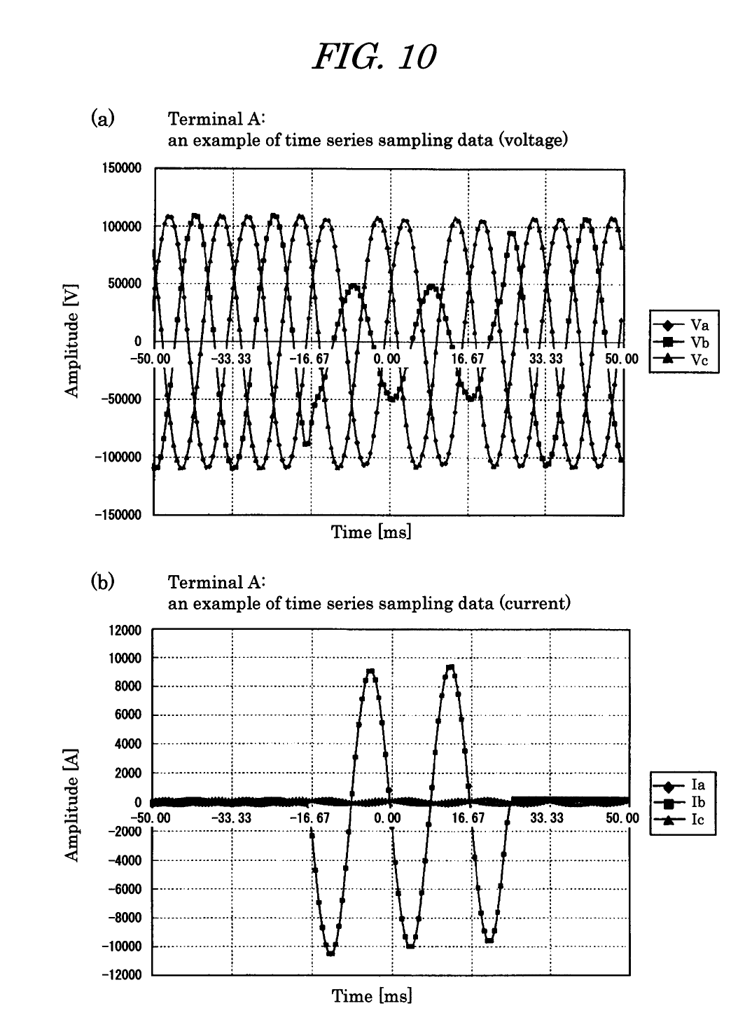

With the explanation described above, a processing function has been explained relating to the input processors 10A and 10B and the location processor 20 that compose the fault location device. Below, the fault location method according to this embodiment will be explained referring to FIGS. 10 through 12.

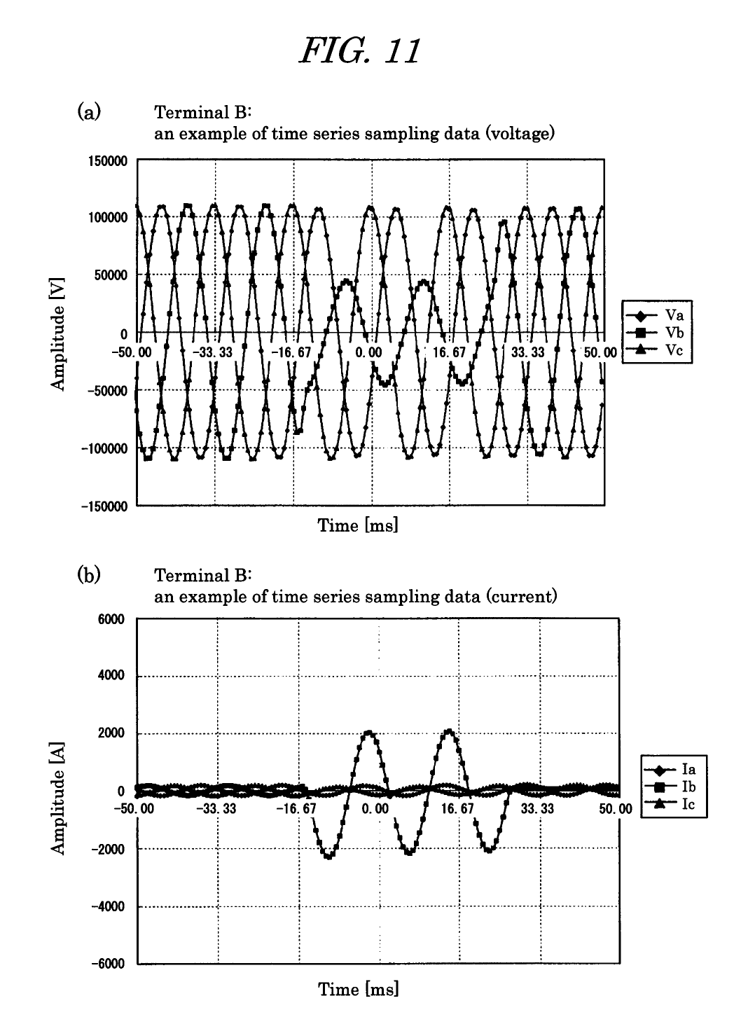

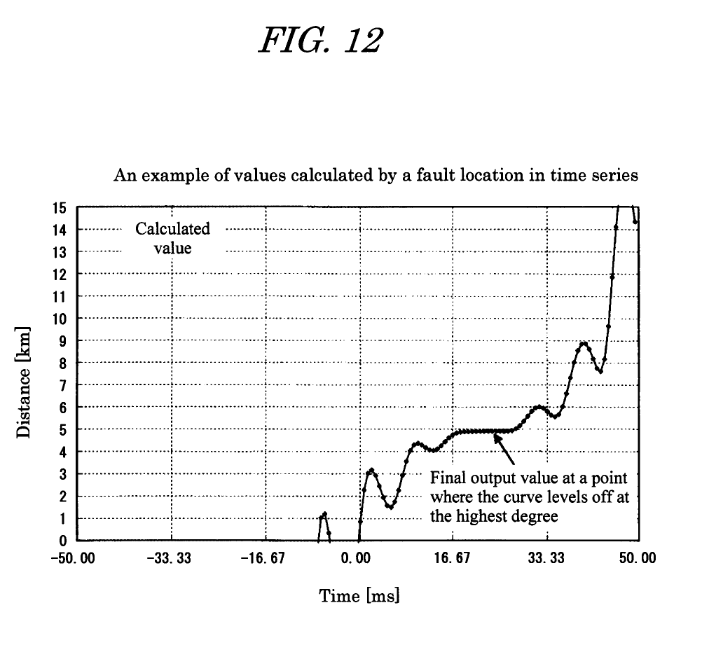

FIGS. 10 through 12 show the fault location method according to this embodiment, FIG. 10(a) shows an example of time series sampling data of voltage at a terminal A, FIG. 10(b) shows an example of time series sampling data of current at the terminal A, FIG. 11(a) shows an example of time series sampling data of voltage at a terminal B, FIG. 11(b) shows an example of time series sampling data of current at the terminal B, and FIG. 12 shows an example of time series values calculated by fault location calculation.

As shown in FIGS. 10 and 11, the method of this embodiment, includes acquiring the signals of the voltage V_{A} (vector quantity), the current I_{A} (vector quantity), the voltage V_{B} (vector quantity) and the current I_{B} (vector quantity), which are sampled at the terminals A and B of the power transmission line section 1 to be located, regardless of the synchronous sampling or asynchronous sampling between the terminals. Note that in the examples shown in FIGS. 10 and 11, the terminal A (FIG. 10) and the terminal B (FIG. 11) are in an asynchronous state each other, and there is a phase shift of approximately 45 degrees between the terminals.

When using the line length L and the transmission line constant Z (vector quantity) per unit length, since values of the second power of a fault point voltage V_{F} (vector quantity) when viewed from the opposite ends of the transmission line section are equal to each other, for the distance x from the terminal A to the fault point 2 (point F), the calculation of amplitude value and phase of each voltage and current from time series sampling data, can provide the expression (29) described below.

Next, a method for finding the expression (29) will be explained.

As a general method of calculating a vector quantity (phasor quantity) from time series sampling data of an electrical quantity, there is a method using a discrete Fourier transform (DFT).

The vector quantity (phasor quantity) can be calculated by the expression (28), with applying the DFT to time series sampling data Vₖ.

$${V}_{S} = j \frac{\sqrt{2}}{N} {\sum }_{k = 0}^{N - 1} {V}_{k} {e}^{- j \frac{2 π k}{N}} \qquad ( 28 )$$

When this expression (28) is applied to the expressions (4) and (8), the following expression (29) can be obtained.

|\dot{V}_{AS}−x·Ż·İ_{AS}|²=|\dot{V}_{F}|²=|\dot{V}_{BS}−(L−x)·Ż·İ_{BS}|² (29)

Here, V_{AS} (vector quantity), I_{AS} (vector quantity), V_{BS} (vector quantity), and I_{BS} (vector quantity), are vector quantities calculated from time series sampling data.

In this embodiment, as with the first and second embodiments described above, by solving a quadratic equation for x obtained from the expression (29), the distance x up to the fault point F can be calculated, as a result of a fault location calculation, values in time series can be obtained as shown in FIG. 12.

Based on this result, a point where the calculated values level off at the highest degree is found by judgment of convergence, and the point is used as a final location result. For example, judgment of convergence is performed by taking as a convergence point a point where the dispersion of values at adjacent three points is a minimum value.

As described above, with the third embodiment, as with the first and second embodiments, the distance x up to the fault point can be calculated by a simple and direct calculation without requiring no synchronization between terminals. Moreover, in the method of this embodiment, judgment of convergence is performed for values calculated in time series by location calculation, and a final location result is decided and output in accordance with the judgment result. This method can withstand the transient fluctuation of data and the accuracy of measurement can be improved more.

### Fourth Embodiment

The configuration of a fault location device for implementing a fault location method according to the fourth embodiment, is the same as that of the first through third embodiments. In addition, the input processor 10 also is the same as that of the first through third embodiments.

Since a different feature of this embodiment from the first through third embodiments, is only a part of the processing function of the location processor 20, below, the different processing function of the location processor 20 is mainly explained.

### {Configuration}

As with the first through third embodiments, in this embodiment, the input processors 10 shown in FIG. 1, acquire the signals of the voltage V_{A} (vector quantity), the current I_{A} (vector quantity), the voltage V_{B} (vector quantity) and the current I_{B} (vector quantity), which are sampled at the terminals A and B of the power transmission line section 1 to be located, regardless of the synchronous sampling or asynchronous sampling between the terminals.

In addition, the location processor 20, sets in advance the line length L and the transmission line constant Z (vector quantity) per unit length, and calculates the distance x from the terminal A to the fault point F using the amplitude of a vector quantity (phasor quantity) or a point in time where the phasor quantity levels off at the highest degree.

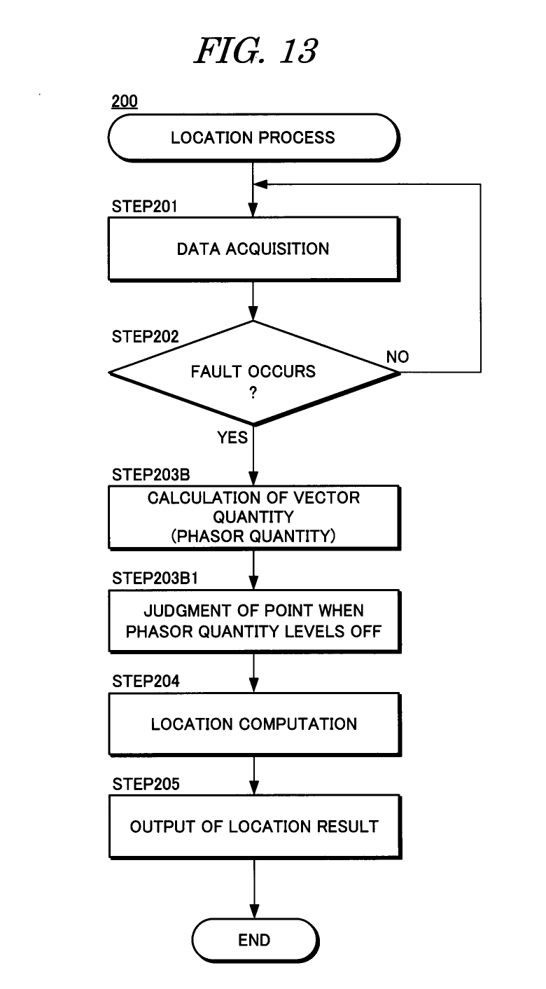

FIG. 13 is a flowchart showing a location process 200 that is performed as a processing function of the location processor 20 in the fault location device for implementing the fault location method according to the fourth embodiment.

In FIG. 13, the location processor 20 acquires data at step 201. This step 201 is a processing step performed by the data acquisition part 21 shown in FIG. 1.

After acquiring the data at step 201, when the location processor 20 has determined that a fault occurs at step 202 (“Yes” of step 202), the location processor 20 calculates a vector quantity (phasor quantity) at next step 203B, and furthermore, judges the amplitude of the vector quantity (phasor quantity) or a point in time where the phasor quantity levels off at the highest degree at step 203B1, subsequently, performs a location computation using the setting values such as each phase voltage data and each phase current data at the judged point, and the transmission line constant at step 204. These steps 202, 203B, 203B1 and 204 are processing steps performed by the location computing part 22 shown in FIG. 1.

Thus, the location processor 20 outputs a location computation result at next step 205. This step 205 is performed by the location result output part 23 shown in FIG. 1.

### {Action}

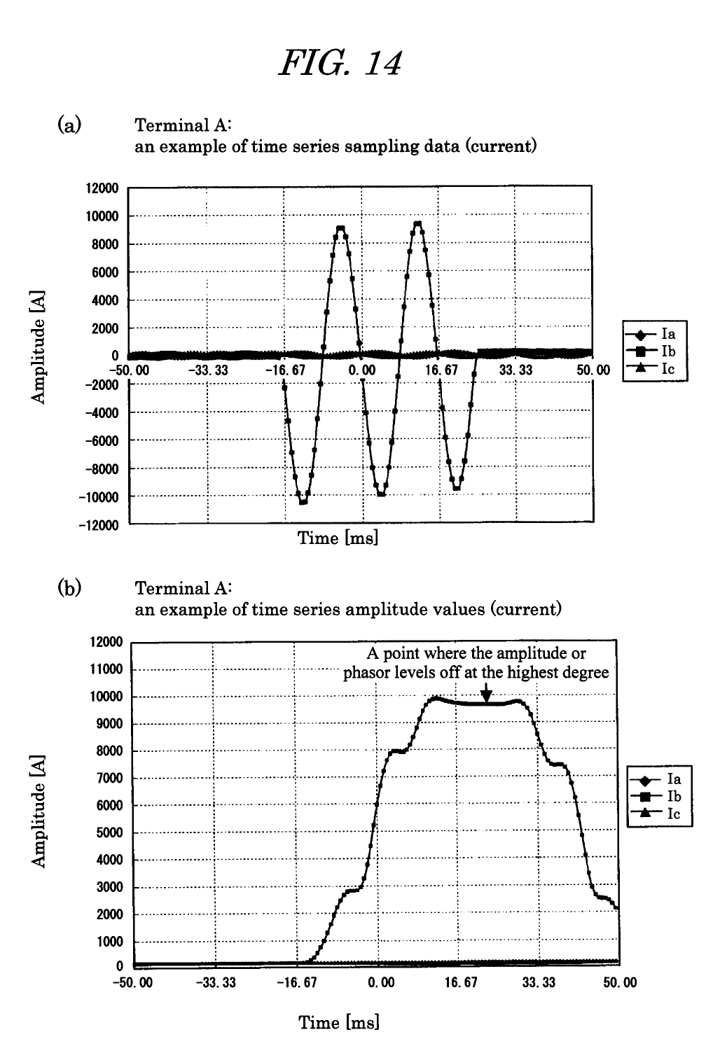

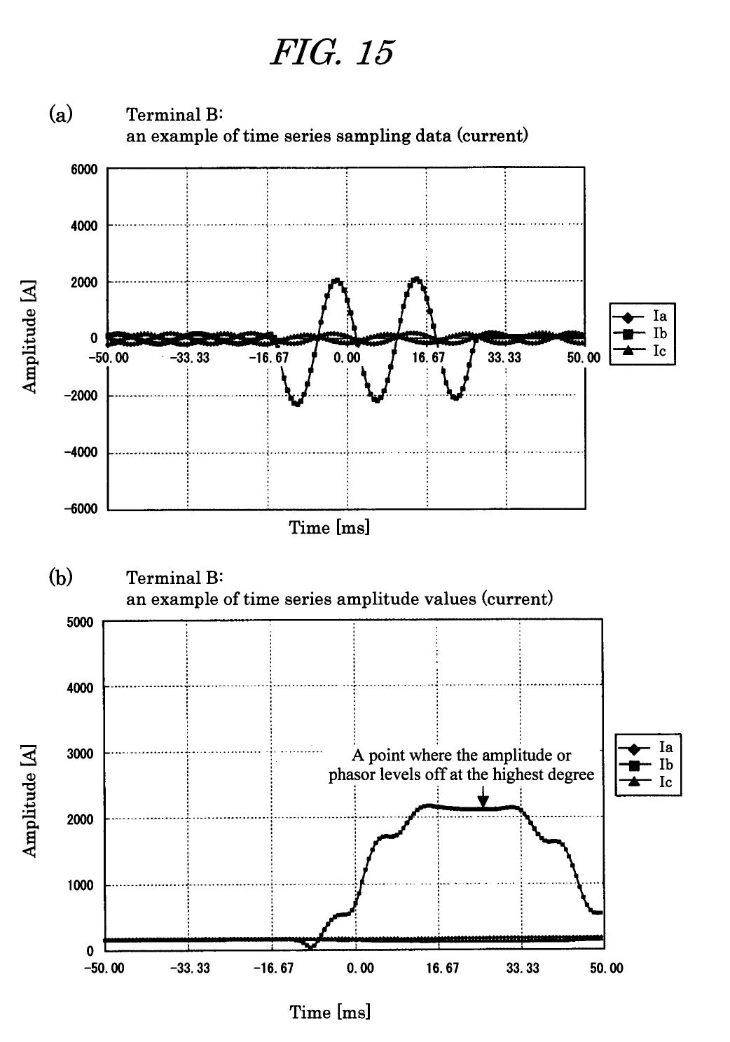

With the explanation described above, a processing function has been explained relating to the input processors 10A and 10B and the location processor 20 that compose the fault location device. Below, the fault location method according to this embodiment will be explained referring to waveforms of FIGS. 14 and 15.

FIGS. 14 and 15 show the fault location method according to this embodiment, FIG. 14(a) shows an example of time series sampling data of current at a terminal A, FIG. 14(b) shows an example of time series amplitude of current at the terminal A, FIG. 15(a) shows an example of time series sampling data of current at a terminal B, and FIG. 15(b) shows an example of time series amplitude of current at the terminal B.

As shown in FIGS. 14(a) and 15(a), the method of this embodiment, includes acquiring the signals of the voltage V_{A} (vector quantity), the current I_{A} (vector quantity), the voltage V_{B} (vector quantity) and the current I_{B} (vector quantity), which are sampled at the terminals A and B of the power transmission line section 1 to be located, regardless of the synchronous sampling or asynchronous sampling between the terminals.

As shown in FIGS. 14(b) and 15(b), when using data at a point in time where time series sampling data level off at the highest degree and the line length L and the transmission line constant Z (vector quantity) per unit length, since values of the second power of a fault point voltage V_{F} (vector quantity) when viewed from the opposite ends of the transmission line section are equal to each other, for the distance x from the terminal A to the fault point F, the following expression (30) can be obtained.

|\dot{V}_{AT}−x·Ż·İ_{AT}|²=|\dot{V}_{F}|²=|\dot{V}_{BT}−(L−x)·Ż·İ_{BT}|² (30)

Here, V_{AT} (vector quantity), I_{AT} (vector quantity), V_{BT} (vector quantity), and I_{BT} (vector quantity), are vector quantities at the point where time series sampling data level off at the highest degree, calculated from the time series sampling data.

By solving a quadratic equation for x obtained from the expression (30), the distance x up to the fault point F at a point in time where time series sampling data level off at the highest degree, can be calculated.

For example, the point in time where time series sampling data level off at the highest degree may be a point in time where the dispersion of values at adjacent three points is a minimum value in the amplitude value of each time series voltage or current or phasor value. Note that in the examples shown in FIGS. 14 and 15, the terminal A (FIG. 14) and the terminal B (FIG. 15) are in an asynchronous state each other, and for the point in time where the amplitude or phasor quantity levels off at the highest degree, there is a time lag of approximately 2 ms between the terminals.

As described above, with the fourth embodiment, as with the first through third embodiments, the distance x up to the fault point can be calculated by a simple and direct calculation without requiring no synchronization between terminals. Moreover, in the method of this embodiment, the distance x up to the fault point is calculated by using a value at a point in time where the amplitude or phasor quantity levels off at the highest degree. This method can withstand the transient fluctuation of data and the accuracy of measurement can be improved more.

### Fifth Embodiment

In the first through fourth embodiments, the power transmission line section 1 to be located has two terminals. However, in the fifth embodiment, the power transmission line section 1 to be located has a branch point and three terminals including a terminal at the branch point, as a result, another input processor is added. In this embodiment, except the additional input processor, the configuration of the input processor 10 is the same as that of the first embodiment. However, due to the branch point, a part of the processing function of the location processor 20 of this embodiment is different from that of the first embodiment.

### {Configuration}

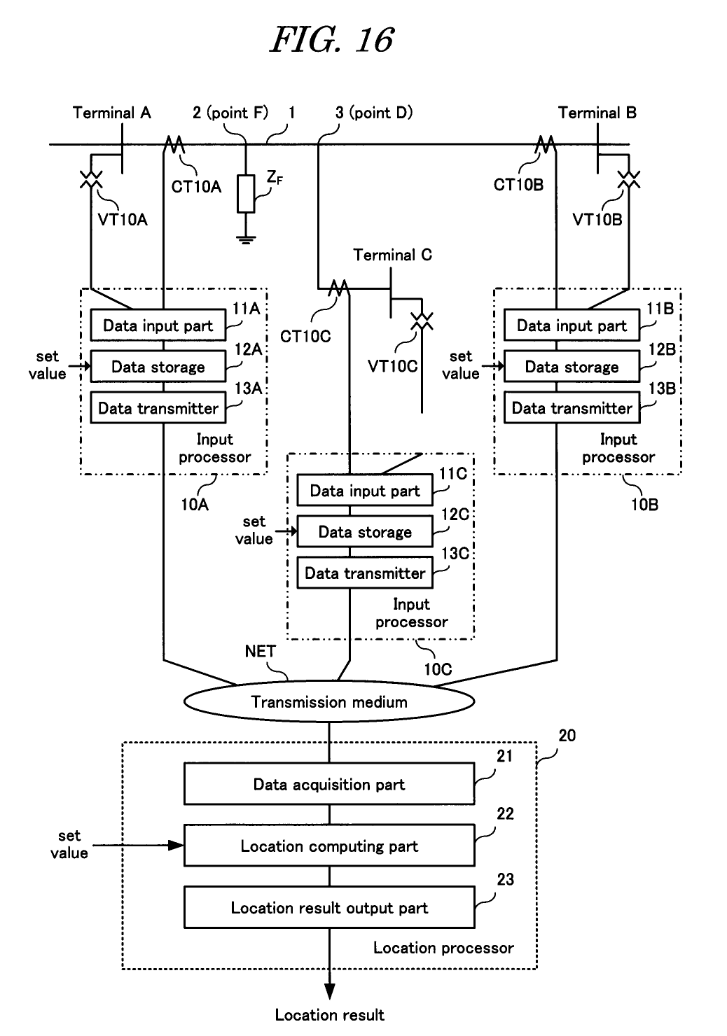

In FIG. 16, symbols “CT10C” and “VT10C” respectively denote a current transformer and a voltage transformer provided at a terminal C. A symbol “10C” denotes an input processor provided at the terminal C. The input processor 10C is composed of a data input part 11C, a data storage 12C and data transmitter 13C, and connected with the transmission medium NET. The location processor 20 is the same as that shown in FIG. 1.

As with the first through fourth embodiments, in this embodiment, the input processors 10 shown in FIG. 1, acquire the signals of the voltage V_{A} (vector quantity), the current I_{A} (vector quantity), the voltage V_{B} (vector quantity) and the current I_{B} (vector quantity), which are sampled at the terminals A and B of the power transmission line section 1 to be located, regardless of the synchronous sampling or asynchronous sampling between the terminals. And furthermore, in this embodiment, the input processors 10 acquire the voltage V_{C} (vector quantity) and the current I_{C} (vector quantity), which is sampled at the terminal C.

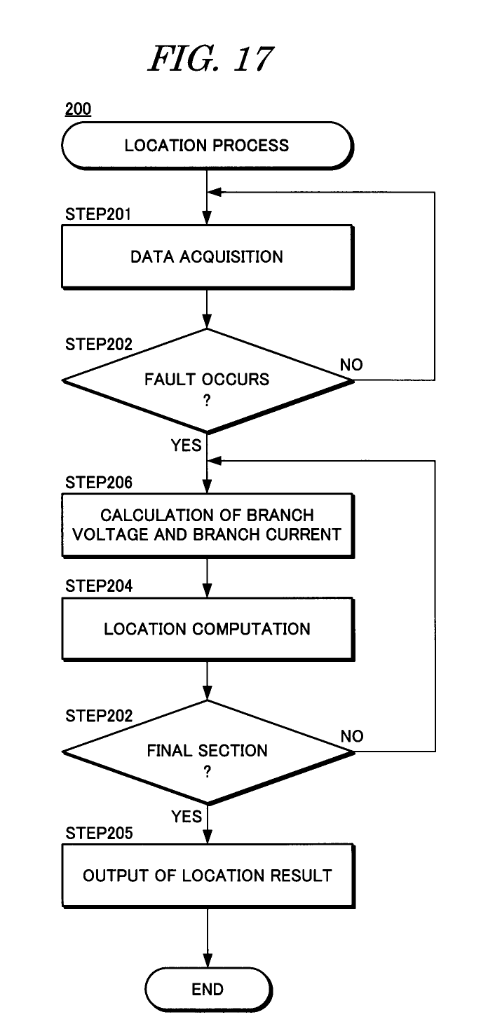

A processing function of the location processor 20 of this embodiment, will be explained referring to the flowchart of FIG. 17.

In FIG. 17, the location processor 20 acquires data at step 201. This step 201 is a processing step performed by the data acquisition part 21 shown in FIG. 1.

After acquiring the data at step 201, when the location processor 20 has determined that a fault occurs at step 202 (“Yes” of step 202), the location processor 20 calculates a branch voltage and a branch current at next step 206, performs a location computation using the setting values such as each phase voltage data and each phase current data, and the transmission line constant at next step 204, and decides on the fault point or judges whether the selected section at this time is a final section at subsequent step 207. These steps 202, 206, 204 and 207 are processing steps performed by the location computing part 22 shown in FIG. 1.

Thus, the location processor 20 outputs a location computation result at next step 205. This step 205 is performed by the location result output part 23 shown in FIG. 1.

### {Action}

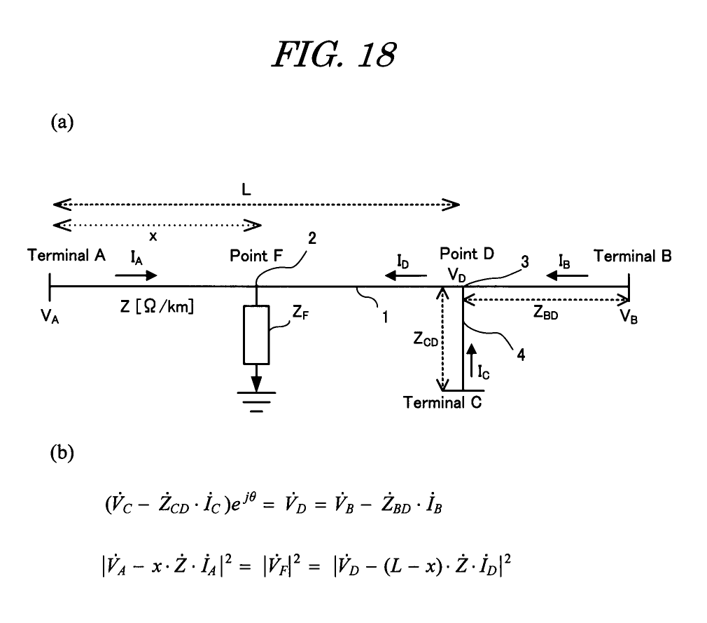

With the explanation described above, a processing function has been explained relating to the input processors 10A and 10B and the location processor 20 that compose the fault location device. Below, the fault location method according to this embodiment will be explained referring to FIG. 18.

FIGS. 18(a) and 18(b) show a fault location method according to the fifth embodiment, FIG. 18(a) is a circuit diagram showing a power transmission line, and FIG. 18(b) is a view showing a relationship that can be established between voltage and current.

In this embodiment, as shown in FIG. 18, the power transmission line 1 branches at a branch point D that is positioned in the middle of the range from the terminal A to the terminal B, and has a terminal C at the branch point D. When as a section to be located in the power transmission line 1, the section A-D from the terminal A to the branch point D is selected, since values of the second power of a branch point voltage V_{D} (vector quantity) of the branch point D when viewed from the terminals B and C are equal to each other, when the phase shift between the terminals B and C is denoted by “A”, the following expression (31) can be established.

(\dot{V}_{C}−Ż_{CD}·İ_{C})e^{jθ}=\dot{V}_{D}=\dot{V}_{B}−Ż_{BD}·İ_{B} (31)

From the expression (31), the following expression (32) can be found.

Branch point voltage: \dot{V}_{D}=\dot{V}_{B}−Ż_{BD}·İ_{B}

Branch point current: İ_{D}=İ_{B}+İ_{C}e^{jθ} (32)

When using the signals of the voltages V_{A} (vector quantity) and V_{D} (vector quantity), and the currents I_{A} (vector quantity) and I_{D} (vector quantity), which are sampled at the terminal A and the point D in the section A-D of the power transmission line 1 to be located, regardless of the synchronous sampling or asynchronous sampling between the both ends, and when using the line length L and the transmission line constant Z (vector quantity) per unit length, since values of the second power of a fault point voltage V_{F} (vector quantity) when viewed from the terminal A and the point D as the both ends of the section A-D are equal to each other, for the distance x from the terminal A to the fault point F, the following expression (31) can be obtained.

|\dot{V}_{A}−x·Ż·İ_{A}|²=|\dot{V}_{F}|²=|\dot{V}_{D}−(L−x)·Ż·İ_{D}|² (33)

When substituting the expression (32) for the expression (33), a quadratic equation for x, can be obtained, which has parameters of voltages and currents of the terminals A, B and C. By solving the quadratic equation for x, the distance x from the terminal A to the fault point F can be calculated.

As described above, with the fifth embodiment, as with the first through fourth embodiments, even if the power transmission line to be located has three or more terminals including a terminal at a branch point, the distance x up to the fault point can be accurately calculated by a simple and direct calculation without requiring no synchronization between terminals.

1. A method for fault location which locates a fault point using a voltage and a current of each terminal in a power transmission line section to be located and a transmission line constant, the method comprising the step of:
calculating a distance from a designated terminal to a fault point by solving a quadratic equation obtained by taking as the fault point a point where values of the second power of a fault point voltage in a fault phase when viewed from opposite ends of the section to be located are equal to each other.

2. The method for fault location according to claim 1,
wherein a transformed value obtained as a result of a mode transformation is used as the fault point voltage.

3. The method for fault location according to claim 1,
wherein time series sampling values of the voltage and the current are used for calculation, and it is determined whether the location results calculated in time series have converged, to output a final result.

4. The method for fault location according to claim 1,
wherein time series sampling values of the voltage and the current are used for calculation, and wherein data obtained at the time point where the time series sampling values levels off is used for calculation.

5. The method for fault location according to claim 1,
wherein, based on that values of branch point voltage when viewed from two terminals are equal to each other in the power transmission line section having a branch point and three or more terminals including a terminal at the branch point, a phase difference between the two terminals is calculated by using the voltage and the current of the two terminals and the transmission line constant, a voltage and a current of the branch point are calculated by using the calculated phase difference, the voltage and the current of the two terminals and the transmission line constant, the distance from the designated terminal from the fault point is calculated by regarding a combination of a terminal and a branch point or a combination of branch points, as the opposite ends.

6. A device for fault location which locates a fault point using a voltage and a current of each terminal in a power transmission line section to be located and a transmission line constant, the device comprising:
an input processor which is provided at each terminal in the power transmission line section to be located, wherein the input processor has:
a data input part which acquires terminal voltage and current signals and converts the signals into digital form,
a data storage which has one or more type of setting value set in advance including a data retention time and stores an electrical quantity data in a memory based on the setting value when a fault occurs, and
a data transmitter which transmits a stored data; and
a location processor which has:
a data acquisition part which acquires data transmitted from the input processor provided at each terminal via a transmission medium,
a location computing part which sets in advance one or more type of setting value including the transmission line constant of the power transmission line to be located, uses the setting value and the current and voltage data acquired by the data acquisition part, and performs a location computation that calculates a distance from a designated terminal to a fault point by solving a quadratic equation obtained by taking as the fault point a point where values of the second power of a fault point voltage in a fault phase when viewed from opposite ends of the section to be located are equal to each other, and
a location result output part which outputs a location result obtained by the location computing part.
